(19) United States
(12) Patent Application Publication
(10) Pub. No.: US 2016/0093353 A1
(43) Pub. Date: Mar. 31, 2016

(54) DUAL STAGE SENSING CURRENT WITH REDUCED PULSE WIDTH FOR READING RESISTIVE MEMORY

(71) Applicant: QUALCOMM Incorporated, San Diego, CA (US)

(72) Inventors: Seong-Ook JUNG, Seoul (KR); Taehui NA, Seoul (KR); Jisu KIM, Seoul (KR); Jung Pill KIM, San Diego, CA (US); Seung Hyuk KANG, San Diego, CA (US)

(21) Appl. No.: 14/499,158

(22) Filed: Sep. 27, 2014

(51) Int. Cl. G11C 11/16

(52) U.S. Cl. CPC G11C 11/1673

(57) ABSTRACT

Systems and methods for reducing a probability of read disturbance during a read operation on a resistive memory bit cell include a dual stage sensing scheme, which is used to reduce pulse widths of sensing currents for reading the resistive memory bit cell. During a first stage of the read operation on the resistive memory bit cell, a first sensing current is passed in a first direction through the resistive memory bit cell, and during a second stage of the read operation, a second sensing current is passed in an opposite, second direction through the resistive memory bit cell. Durations of the first and second stages are each equal to half of the duration of the read operation, which reduces pulse width of the first and second sensing currents. Probability of read disturbance occurring is limited to at most one of the first or second stages.

### FIELD OF DISCLOSURE

Disclosed aspects are directed to reducing probability of read disturbance on a resistive memory bit cell during a read operation, by providing a reduced pulse width sensing current based on a dual stage sensing scheme for the reading operation.

### BACKGROUND

Memory devices conventionally include arrays of bit cells that each store a bit of data. Each data bit can represent a logical zero (“0”) or a logical one (“1”), which may correspond to a state of the bit cell. During a read operation of a selected bit cell, a voltage level close to ground may be representative of “0” and a relatively higher voltage level may be representative of “1”. Bit lines are coupled to various bit cells in the memory array and the bit lines couple the bit cells to other components used in read/write operations.

Magnetoresistive random access memory (MRAM) is a non-volatile memory technology where data is stored based on magnetization polarities of bit cells. In contrast to conventional RAM technologies which store data as electric charges or current flows, MRAM uses magnetic elements. A magnetic tunnel junction (MTJ) which is conventionally used as a storage element or bit cell for MRAM technology, can be formed from two magnetic layers, each of which can hold a magnetic moment, separated by an insulating (tunnel barrier) layer. Conventionally, the fixed layer is set to a particular polarity. The free layer's polarity is free to change to match that of an external magnetic field that can be applied. A change in the polarity of the free layer will change the resistance of the MTJ bit cell. For example, when the magnetization polarities are aligned or “parallel,” a low resistance state exists, which corresponds to a logical “0”. When the magnetization polarities are not aligned or are “anti-parallel,” a high resistance state exists, which corresponds to a logical “1”.

Thus, in magnetoresistive random access memory (MRAM), each bit cell (e.g., a MTJ bit cell) has a resistance value based on whether the bit cell represents a logical zero (“0”) or a logical one (“1”). Specifically, the resistance of the bit cell (R_{data}) relates to the data stored in the bit cell.

Thus, in order to write a logical “0” or a logical “1,” corresponding write currents are passed through the MTJ bit cell to effect a corresponding alignment of the free layer and the fixed layer, or in other words to program the MTJ bit cell to the corresponding resistance state.

In order to read the bit cell, a sensing current I_{data} is passed through the bit cell and a voltage V_{data} developed across the resistance R_{data} is then compared to a reference voltage V_{ref}. If V_{data} is high relative to V_{ref}, then the bit cell is determined to have a logical “1” stored therein. If V_{data} is low relative to V_{ref}, then then the bit cell is determined to have a logical “0” stored therein. The difference between the voltage across the bit cell V_{data} and the reference voltage V_{ref}, (differential voltage ΔV=V_{data}−V_{ref}) is therefore used to indicate the logic state stored in the the bit cell. A sensing margin refers generally refers to the amount by which ΔV must be correctly sensed as positive or negative in order to correctly read the value stored in the bit cell as “1” or “0” respectively.

For the read operation, the sensing current needs to be less than the write currents used for writing the bit cell, in order to ensure that the data stored in the bit cell is not inadvertently flipped or reprogrammed during the read operation. If the read operation results in an undesired change in the logical value stored in the bit cell, this situation is referred to as a read disturbance. A critical current (I_{C}) for an MTJ refers to the amount of current required to switch a resistance state of the MTJ, or in other words, to cause a read disturbance. Thus, I_{data} must be less than I_{C} in order to prevent a read disturbance.

A clamp transistor (e.g., a n-channel metal oxide semiconductor (NMOS) transistor) may be used to drive the sensing current through the bit cell. A gate voltage of the clamp transistor (or a clamp voltage V_{G}_{_}_{clamp}) is adjusted or controlled in order to vary the amount of sensing current that is passed through the bit cell for a read operation. It may be desirable to maintain the clamp voltage V_{G}_{_}_{clamp} to a low value, in order to keep the sensing current low and thus avoiding read disturbance.

However, a lower limit on the sensing current is imposed due to the dependence of the clamp voltage V_{G}_{_}_{clamp} on a threshold voltage (Vₜₕ) of the clamp transistor. The threshold voltage of the clamp transistor is the minimum voltage that needs to be applied to the gate of the clamp transistor in order to activate the clamp transistor and cause it to drive the sensing current. If the clamp voltage V_{G}_{_}_{clamp} is too low, then there is a risk that the clamp voltage V_{G}_{_}_{clamp} may be lower than the threshold voltage Vₜₕ, which would prevent any sensing current from being driven to the bit cell. Thus, the sensing current is dependent on the difference between the clamp voltage V_{G}_{_}_{clamp} and the threshold voltage Vₜₕ, which means that the magnitude of the sensing current cannot be reduced to a very low value in an effort to avoid the read disturbance.

Moreover, reducing the sensing current to a very low value can also lead to a smaller sensing margin. A read access pass yield (RAPY) refers to a measure of a yield or percentage of read operations which result in a correct read value for a bit cell. Similarly, a read disturbance pass yield (RDPY) refers to a measure of yield or percentage of read operations which are not affected by read disturbance issues. A low sensing current can lead to undesirably low RAPY and RDPY.

Accordingly, there is continuing need in the art for providing sensing currents which can lead to sufficient sensing margin, but also avoid read disturbance issues, while avoiding the aforementioned drawbacks with reducing the magnitude of the sensing current.

### SUMMARY

Systems and methods are directed to reducing a probability of read disturbance during read operations on a resistive memory bit cell, by using a dual stage sensing scheme to reduce pulse widths of sensing currents for reading the resistive memory bit cell.

For example, an exemplary aspect is directed to a method of reading a resistive memory bit cell, the method comprising: during a first stage of a read operation on the resistive memory bit cell, passing a first sensing current in a first direction through the resistive memory bit cell, and during a second stage of the read operation, passing a second sensing current in a second direction through the resistive memory bit cell. A duration of the first stage and a duration of the second stage are equal to half of a duration of the read operation, and wherein the first direction is opposite to the second direction.

Another exemplary aspect is directed to a circuit comprising: a resistive memory bit cell. The circuit further comprises a sensing circuit configured to, during a first stage of a read operation on the resistive memory bit cell, pass a first sensing current in a first direction through the resistive memory bit cell. The sensing circuit is further configured to, during a second stage of the read operation, pass a second sensing current in a second direction through the resistive memory bit cell. A duration of the first stage and a duration of the second stage are equal to half of a duration of the read operation, and wherein the first direction is opposite to the second direction.

Yet another exemplary aspect is directed to a system comprising: means for passing a first sensing current in a first direction through a resistive memory bit cell during a first stage of a read operation on the resistive memory bit cell, and means for passing a second sensing current in a second direction through the resistive memory bit cell during a second stage of the read operation. A duration of the first stage and a duration of the second stage are equal to half of a duration of the read operation, and wherein the first direction is opposite to the second direction.

### BRIEF DESCRIPTION OF THE DRAWINGS

The accompanying drawings are presented to aid in the description of embodiments of the invention and are provided solely for illustration of the embodiments and not limitation.

FIGS. 1A-C illustrate an exemplary circuit 100 configured for dual stage sensing of a resistive memory bit cell.

FIG. 2 illustrates sense amplifier 200 configured to cooperate with circuit 100.

FIG. 3 illustrates a flow chart related to a method of dual stage sensing of a resistive memory bit cell, according to exemplary aspects.

FIG. 4 illustrates a block diagram showing an exemplary wireless device in which exemplary aspects may be advantageously employed.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Conventional efforts for avoiding read disturbance during read operations on resistive memory bit cells focus on reducing a magnitude of the sensing current. On the other hand, an alternative approach to reducing the likelihood of read disturbance involves reducing a pulse width of the switching current. This is because with a shorter pulse width of the sensing current, the critical current I_{C} can be avoided. Exemplary aspects are directed to systems and techniques for reducing the pulse width of the sensing current while being able to deliver sufficient sensing margin for correctly reading data stored in bit cell (e.g., an MTJ bit cell of a MRAM array).

More specifically, a dual stage sensing scheme is described in an exemplary aspect, wherein a read operation is performed with two pulses of sensing currents, one in each stage. Each pulse of the sensing current traverses the bit cell in an opposite direction relative to one another. Each pulse is of half the width of the pulse width of a conventional sensing current which only traverses the bit cell in a single stage and in a single direction. In this manner, the probability that each half-width pulse in exemplary aspects may cause a read disturbance is minimized As such, any likelihood of read disturbance would be limited to a single direction of current flow through the bit cell, and thus, to only one of the two stages.

In this manner, RAPY and RDPY are improved by reducing the pulse width of the sensing current in exemplary aspects. The probability of the read disturbance is a function of the sensing current (I_{data}) and pulse width (τ_{data}) of the sensing current that is passed through a bit cell. For an appropriate value of pulse width τ_{data}, the critical current I_{C} is defined as

$$\frac{1}{{S}_{data} \cdot {τ}_{data }} .$$

A read disturbance margin (RDM) relates to a measure of a margin by which the sensing current avoids read disturbance or in other words, a difference between I_{C} and I_{data}. RDM can be defined by the following equation, where RDM may be expressed in micro-amperes (μA).

$$RDM = {I}_{C} - {I}_{data} = \frac{1}{{S}_{data } \cdot {τ}_{data}} - {I}_{data}$$

Thus, it is seen that when the pulse width decreases, RDM increases, which means that the sensing current can avoid read disturbance by a higher margin. This also means that the number of cells which will be correctly read, or the RAPY, is increased. The effect of decreasing the pulse width on RDPY can also be similarly described with reference to the below equation for RDPY in units of standard deviation σ, where μ_{I}_{_{C}} and σ_{I}_{_{C}} are the mean and standard deviation of I_{C}, respectively, and μ_{I}_{_{data}} and σ_{I}_{_{data}} are the mean and standard deviation of I_{data}.

$$RDPY = \frac{{μ}_{{I}_{C}} - {μ}_{{I}_{data}}}{\sqrt{{σ}_{{I}_{C}}^{2} + {σ}_{{I}_{data }}^{2}}}$$

As pulse width τ_{data} decreases, the critical current I_{C} increases. From the above equation of RDPY, this increase in critical current (Ic) leads to an increase or improvement in the RDPY.

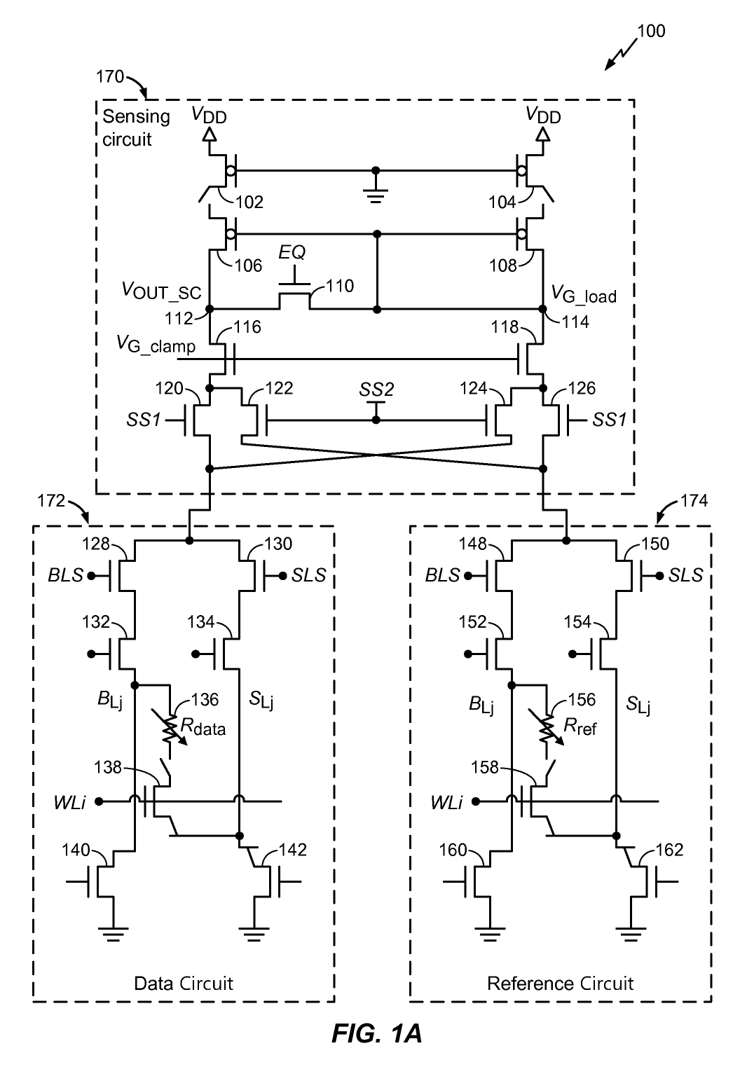

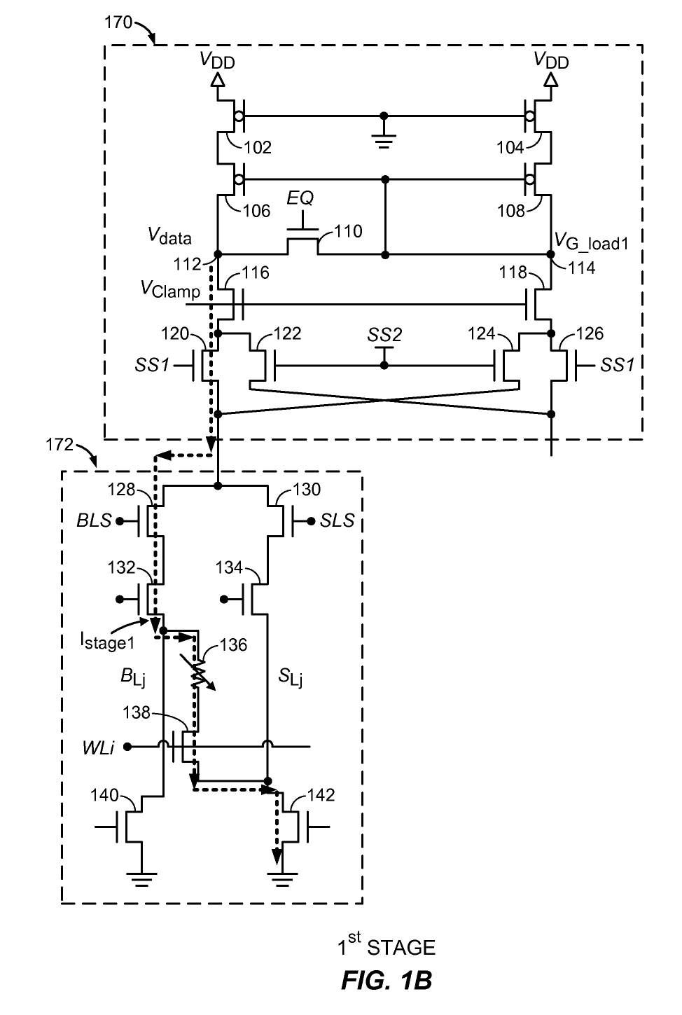

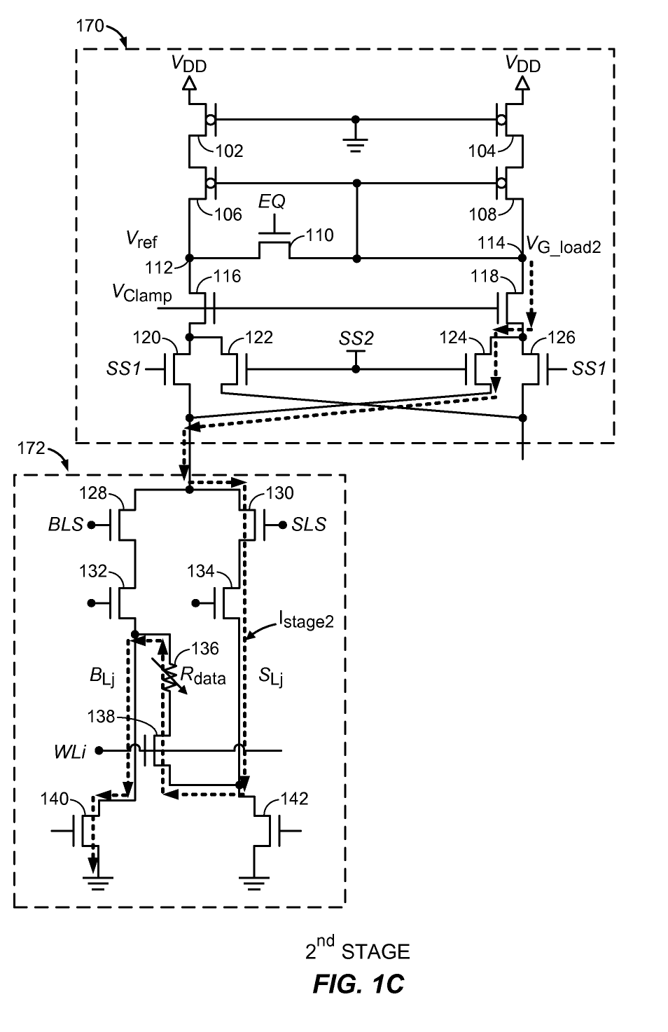

With reference now to FIG. 1A, read circuitry configured for a dual stage sensing operation with half-width pulses of sensing currents, according to exemplary aspects, is illustrated. More specifically, circuit 100 may be utilized for reading a bit cell in an MRAM array. Circuit 100 includes sensing circuit 170, data circuit 172, and reference circuit 174. Sensing circuit 170 is configured as a dual stage sensing circuit. The operation of these circuits in each of the two stages will be discussed in further detail with reference to FIGS. 1B-C. In general, sensing circuit 170 is configured to sense a difference between data voltage V_{data} developed across bit cell 136 in data circuit 172 and reference voltage V_{ref} developed across reference cell 156 in reference circuit 174. In exemplary aspects, data voltage V_{data} is developed in the first stage and reference voltage V_{ref} is developed at the second stage. Upon completion of the second stage the difference between the data voltage and reference voltage, i.e., ΔV=V_{data}−V_{ref} is sensed for determining the value stored in bit cell 136 (once again, if ΔV is positive, then the value stored in bit cell 136 is read as a logical value “1” and if ΔV is negative, the value stored in bit cell 136 is read as a logical value “0.”)

In further detail, data circuit 172 includes bit cell 136, which may be an MTJ. Bit cell 136 may be in a row “i” and column “j” of the MRAM array, and thus, may be selected by the word line WLᵢ and bit-line, source-line pair BLⱼ, SLⱼ, respectively. The same word line WLᵢ and bit-line, source-line pair BLⱼ, SLⱼ, are also used to select reference cell 156 in reference circuit 174 for a sensing operation of bit cell 136. Access transistors 138 and 158 are activated by word line WLᵢ during a read operation. Pull-down transistors 140, 160 and 142, 162 (e.g., n-channel metal oxide semiconductor (NMOS transistors) may enable current flow through selected bit cell 136 and reference cell 156. Column selection transistors 132, 134, 152 and 154 (e.g., NMOS transistors) may be used to select bit cell 136 and reference cell 156 in column “j” among the several other bit cells (not shown) that may be present in row “i.” As will be further discussed, a BL/SL selection MUX (not shown) will be used to activate the control signal BLS or SLS based on whether circuit 100 is operating in the first stage or the second stage. Accordingly, BL selection transistors 128 and 148 (e.g., NMOS transistors) may be enabled by the control signal BLS and SL selection transistors 130 and 150 may be enabled by the control signal SLS. Current flows through bit cell 136 in one of two directions based on which one of the control signals BLS and SLS are high.

With combined reference now to FIGS. 1A-C, in sensing circuit 170, stage selection transistors 120 and 126 (e.g., NMOS transistors) are enabled by control signal SS1 in a first stage (see FIG. 1B) and stage selection transistors 122 and 124 (e.g., NMOS transistors) are enabled by control signal SS2 in a second stage (see FIG. 1C). The voltage clamp signal V_{G}_{_}_{clamp} is supplied by an external source and is used to clamp the gate voltages of data clamp transistor 116 (e.g., an NMOS transistor) and reference clamp transistor 118 (e.g., an NMOS transistor). Thus, V_{G}_{_}_{clamp} controls the current passing through bit cell 136 and reference cell 156. During a read operation, data voltage V_{data} is developed at node 112 and reference voltage V_{ref} is developed at node 114.

Equalization transistor 110 (e.g., an NMOS transistor) is controlled by equalization signal EQ. Data load transistor 106 (e.g., a p-channel metal oxide semiconductor (PMOS) transistor) and reference load transistor 108 (e.g., a PMOS transistor) are diode-connected. Reference load transistor 108 is coupled to reference node 114 at which reference gate voltage V_{G}_{_}_{load} is generated. Once the read operation is completed, the output, i.e., the data value stored in bit cell 136 is available at output node 112 which provides output V_{OUT}_{_}_{SC}. Degeneration transistors 102 and 104 (e.g., PMOS transistors) are activated by coupling their gates to ground voltage and one of their terminals (e.g., source terminal) coupled to positive power supply voltage V_{dd}.

With reference now to FIG. 1B, a first stage of the dual-stage sensing operation will be described. The first stage is entered by turning on the stage selection signal SS1 and turning off the stage selection signal SS2. In the first stage, the BL/SL selection MUX drives the control signal BLS high and SLS low. Initially, at a starting point of the first stage, equalization signal EQ is driven high to turn on equalization transistor 110, which equalizes nodes 112 and 114 to the same voltage. Nodes 112 and 114 are rapidly charged through degeneration PMOS transistors 102 and 104, which leads to an improvement in sensing speed. Once nodes 112 and 114 are equalized and charged, the equalization signal EQ is driven low, which causes equalization transistor 110 to be turned off, thus, decoupling nodes 112 and 114. A first reference gate voltage V_{G}_{_}_{load1} appears at reference node 114 in this first stage, based on reference cell 156.

On the data side, current I_{stage1} flows through data clamp transistor 112, stage selection transistor 120, BL selection transistor 128 (since control signal BLS is high), column selection transistor 132, into bit cell 136 in a first direction, and through access transistor 138 and pull-down transistor 142. The current I_{stage1} is a first pulse of the sensing current for reading bit cell 136, passed in the first direction (i.e., from bit-line BLⱼ to source-line SLⱼ). The current I_{stage1} is passed for half the duration of the read operation, or in some aspects, half the duration for which the word line WLᵢ is activated for the read operation. At node 112, the voltage data voltage V_{data} is formed. It is noted that V_{data} at node 112 in the first stage is based on the first reference gate voltage V_{G}_{_}_{load1} at node 114. The data voltage V_{data} developed in the first stage is stored in a first storage means such as a first capacitor, until the second stage completes (at which point, V_{ref} will be available, for determining ΔV=V_{data}−V_{ref} in a sense amplifier). The first capacitor may comprise, for example, gate capacitors and diffusion capacitors of the transistors (e.g., NMOS and PMOS) in circuit 100.

With reference now to FIG. 1C, a second stage of the dual-stage sensing operation will be described. The second stage is entered by turning on the stage selection signal SS2 and turning off the stage selection signal SS1. In the second stage, the BL/SL selection MUX drives the control signal BLS low and SLS high. Once again, at a starting point of the second stage, equalization signal EQ is driven high to turn on equalization transistor 110, which resets nodes 112 and 114 to the same voltage. Following this, the equalization signal EQ is driven low, which causes equalization transistor 110 to be turned off, severing the connection between nodes 112 and 114.

In the second stage, a second reference gate voltage V_{G}_{_}_{load2} appears at node 114, based on bit cell 136. In more detail, in the second stage, current I_{stage2} flows through reference clamp transistor 118, stage selection transistor 124, SL selection transistor 130 (since control signal SLS is high), column selection transistor 134, access transistor 138 into bit cell 136 in a second direction, and pull-down transistor 140. The current I_{stage2} is a second pulse of the sensing current for reading bit cell 136, passed in the second direction (i.e., from source-line SLⱼ to bit-line BLⱼ). The current I_{stage2} is also passed for half the duration of the read operation, or in some aspects, half the duration for which the word line WLᵢ is activated for the read operation. At node 112, reference voltage V_{ref} is formed based on the second reference gate voltage V_{G}_{_}_{load2}. Reference voltage Vref is stored in a second storage means such as a second capacitor. The second capacitor may also comprise, for example, gate capacitors and diffusion capacitors of the transistors (e.g., NMOS and PMOS) in circuit 100.

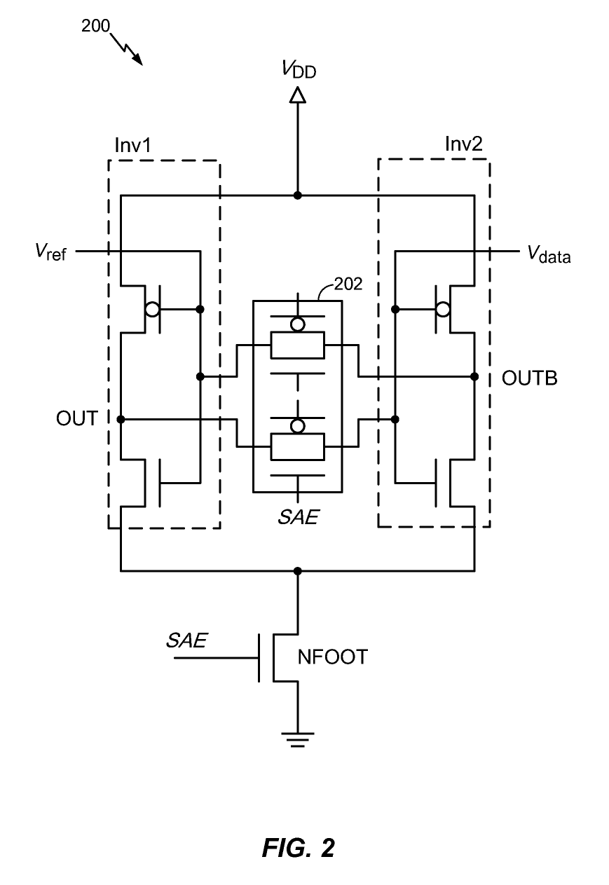

With reference to FIG. 2, sense amplifier 200 is illustrated. Sense amplifier 200 may be coupled to dual-stage sensing circuit 100 in order to amplify the voltage difference ΔV, between the data voltage V_{data}, available at node 112, at the end of the first stage, and reference voltage V_{ref}, also available at node 112, at the end of the second stage. Sense amplifier 200 may be a voltage level sense amplifier (VLSA) which includes inverters Inv1 and Inv2. Transmission gate switches 202, controlled by the signal SAE, may isolate the two output nodes OUT and OUTB from each other, which prevents capacitive coupling between these nodes. Output nodes OUT and OUTB may be equalized or precharged to VDD before signal SAE is driven high. Sense amplifier 200 may also include a foot switch transistor NFOOT to prevent a static current path which may be caused by precharging of the output nodes. Sense amplifier 200 may be activated using signal SAE after the dual-stage operation is completed, as described previously, at which point, V_{data} and V_{ref} would have been stored in the first and second capacitors. After the dual-stage operation, when signal SAE is driven high and sense amplifier 200 is activated. This causes transmission gate switches 202 to complete the cross-coupling connections between the inverters Inv1 an Inv2, which magnifies the difference between V_{data} and V_{ref} and causes the voltages of the output nodes OUT and OUTB to become rail-to-rail voltages corresponding to a logical value of “0” on one output node and “1” on the other output node. Sense amplifier 200 may be coupled to circuit 100 using pass gates and staged enable signals such that the values of V_{ref} and V_{data} available at different times from the same node may be transferred to inputs of sense amplifier 200. A further detailed explanation of the cooperation of sense amplifier 200 with circuit 100 will be avoided in this disclosure, for the sake of brevity.

Since the data voltage V_{data} and reference voltage V_{ref} are both available at the same node 112 at the end of the second stage, the effects of voltage offsets which may arise between nodes 112 and 114 due to process variations, will be cancelled out. This is also known as offset cancellation.

Further, due to the first and second gate voltages V_{G}_{_}_{load1} and _{VG}_{_}_{load2} that are available at node 114 coupled to reference load transistor 108, a doubled sensing margin is provided in exemplary aspects. Furthermore, due to the opposite directions of currents current I_{stage1} and I_{stage2} in the first and second stages passing through bit cell 136, the probability of read disturbance only arises in one of the two stages.

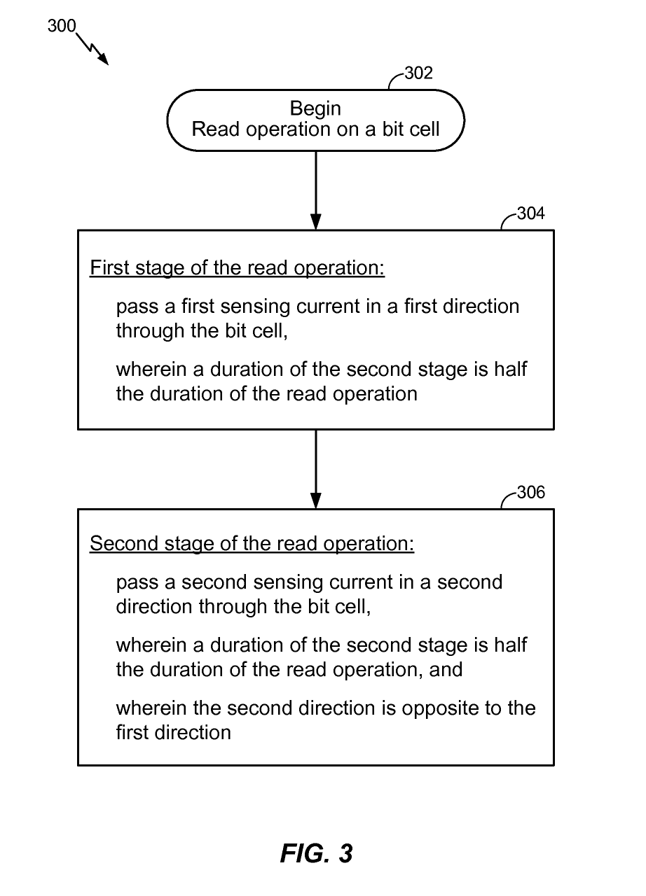

It will be appreciated that exemplary aspects include various methods for performing the processes, functions and/or algorithms disclosed herein. For example, as illustrated in FIG. 3, an exemplary aspect can include a method (300) of reading a resistive memory bit cell (e.g., 136). At Block 302, the method for reading the bit cell begins. During a first stage of the read operation on the bit cell (Block 304) a first sensing current (e.g., I_{stage1}) is passed in a first direction through the bit cell. During a second stage of the read operation (Block 306), a second sensing current (e.g., I_{stage2}) is passed in a second direction through the bit cell. In method 300, the duration of the first stage and a duration of the second stage are equal to half of a duration of the read operation, and the first direction is opposite to the second direction.

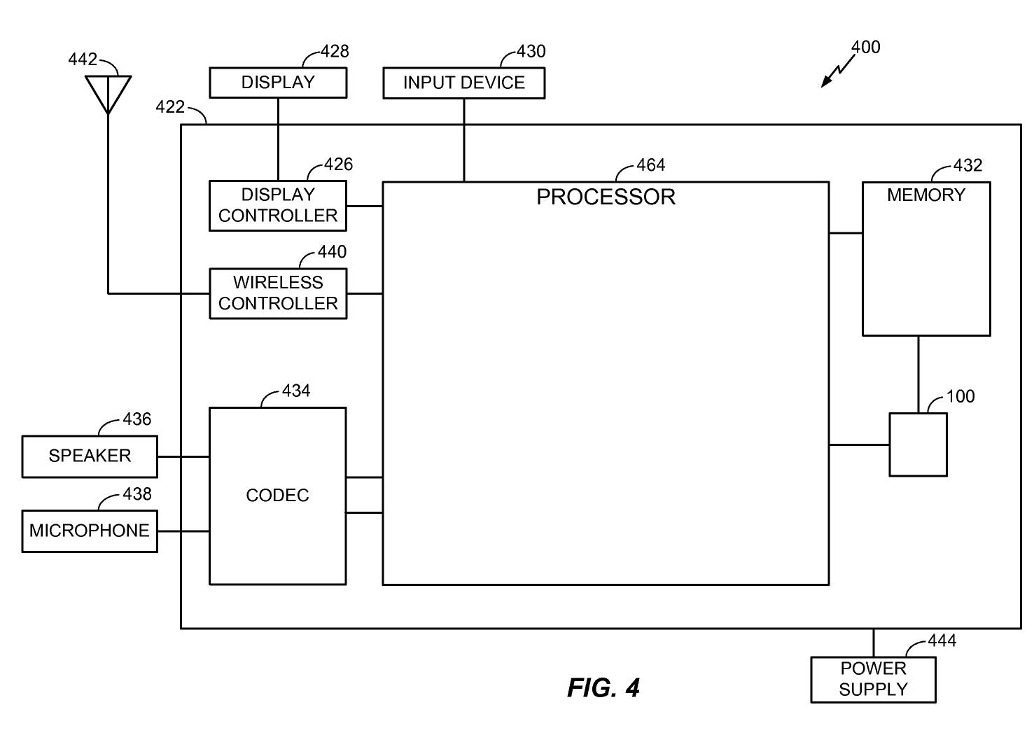

Referring to FIG. 4, a block diagram of a particular illustrative aspect of wireless device 400 configured according to exemplary aspects is depicted. Wireless device 400 includes processor coupled to memory 1432. Memory 1432 may include a MRAM array, and processor 1464 and memory 1432 may be coupled to circuit 100 for sensing operations on MRAM bit cells of the MRAM array in one aspect. FIG. 4 also shows display controller 426 that is coupled to processor 464 and to display 428. Coder/decoder (CODEC) 434 (e.g., an audio and/or voice CODEC) can be coupled to processor 464. Other components, such as wireless controller 440 (which may include a modem) are also illustrated. Speaker 436 and microphone 438 can be coupled to CODEC 434. FIG. 4 also indicates that wireless controller 440 can be coupled to wireless antenna 442. In a particular aspect, processor 464, display controller 426, memory 432, CODEC 434, and wireless controller 440 are included in a system-in-package or system-on-chip device 422.

In a particular aspect, input device 430 and power supply 444 are coupled to the system-on-chip device 422. Moreover, in a particular aspect, as illustrated in FIG. 4, display 428, input device 430, speaker 436, microphone 438, wireless antenna 442, and power supply 444 are external to the system-on-chip device 422. However, each of display 428, input device 430, speaker 436, microphone 438, wireless antenna 442, and power supply 444 can be coupled to a component of the system-on-chip device 422, such as an interface or a controller.

It should be noted that although FIG. 4 depicts a wireless communications device, processor 464 and memory 432 may also be integrated into a set-top box, a music player, a video player, an entertainment unit, a navigation device, a personal digital assistant (PDA), a fixed location data unit, a mobile phone, a smart phone, or a computer, and/or in at least one semiconductor die.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Accordingly, an embodiment of the invention can include a computer readable media embodying a method of reducing read disturbance by implementing a dual or two-stage sensing of resistive memory and by using reduced pulse width sensing currents of opposite directions in the two stages. Accordingly, the invention is not limited to illustrated examples and any means for performing the functionality described herein are included in embodiments of the invention.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of reading a resistive memory bit cell, the method comprising:
during a first stage of a read operation on the resistive memory bit cell, passing a first sensing current in a first direction through the resistive memory bit cell; and
during a second stage of the read operation, passing a second sensing current in a second direction through the resistive memory bit cell;
wherein a duration of the first stage and a duration of the second stage are equal to half of a duration of the read operation, and wherein the first direction is opposite to the second direction and where the duration of the read operation comprises the sum of the duration of the first stage and the duration of the second stage.

2. The method of claim 1, further comprising, during the first stage,
developing a first gate voltage at a reference node coupled to a reference cell;
developing a data voltage at an output node coupled to the resistive memory bit cell, based on the first sensing current and the first gate voltage; and
storing the data voltage in a first capacitor.

3. The method of claim 2, comprising equalizing the output node and the reference node at a start of the first stage.

4. The method of claim 2, further comprising, during the second stage,
developing a second gate voltage at the reference node; and
developing a reference voltage at the output node, based on the second sensing current and the second gate voltage; and
storing the reference voltage in a second capacitor.

5. The method of claim 4, comprising equalizing the output node and the reference node at a start of the second stage.

6. The method of claim 4, further comprising, amplifying, in a sense amplifier, a difference between the data voltage at the output node developed in the first stage and the reference voltage at the output node developed in the second stage.

7. The method of claim 1, wherein a probability of a read disturbance occurring on the resistive memory bit cell is limited to at most one of the first stage or the second stage.

8. The method of claim 1, comprising activating read circuitry for reading the resistive memory bit cell using a word line coupled to the resistive memory bit cell, wherein the word line is driven high for the duration of the read operation.

9. The method of claim 1, wherein the resistive memory bit cell is a magnetoresistive random access memory (MRAM) or magnetic tunnel junction (MTJ) bit cell.

10. A circuit comprising:
a resistive memory bit cell; and
a sensing circuit configured to:
during a first stage of a read operation on the resistive memory bit cell, pass a first sensing current in a first direction through the resistive memory bit cell; and
during a second stage of the read operation, pass a second sensing current in a second direction through the resistive memory bit cell;
wherein a duration of the first stage and a duration of the second stage are equal to half of a duration of the read operation, and wherein the first direction is opposite to the second direction.

11. The circuit of claim 1, further comprising a reference cell and a first capacitor, wherein the sensing circuit is further configured to, during the first stage:
develop a first gate voltage at a reference node coupled to the reference cell;
develop a data voltage at an output node coupled to the resistive memory bit cell, based on the first sensing current and the first gate voltage; and
store the data voltage in the first capacitor.

12. The circuit of claim 11, further comprising a second capacitor, wherein the sensing circuit is further configured to, during the second stage:
develop a second gate voltage at the reference node; and
develop a reference voltage at the output node, based on the second sensing current and the second gate voltage; and
store the reference voltage in the second capacitor.

13. The circuit of claim 12, further comprising an equalization transistor configured to couple and equalize voltages at the output node and the reference node at starting points of the first stage and the second stage.

14. The circuit of claim 10, further comprising a sense amplifier configured to amplify a difference between the data voltage at the output node developed in the first stage and the reference voltage at the output node developed in the second stage.

15. The circuit of claim 10, wherein a probability of occurrence of a read disturbance on the resistive memory bit cell is limited to at most one of the first stage or the second stage.

16. The circuit of claim 10, further comprising a word line coupled to the resistive memory bit cell, wherein the word line is driven high for the duration of the read operation.

17. The circuit of claim 10, wherein the resistive memory bit cell is a magnetoresistive random access memory (MRAM) or magnetic tunnel junction (MTJ) bit cell.

18. The circuit of claim 10 integrated in at least one semiconductor die.

19. The circuit of claim 10, integrated in a device, selected from the group consisting of a set top box, music player, video player, entertainment unit, navigation device, communications device, personal digital assistant (PDA), fixed location data unit, and a computer.

20. A system comprising:
means for passing a first sensing current in a first direction through a resistive memory bit cell during a first stage of a read operation on the resistive memory bit cell; and
means for passing a second sensing current in a second direction through the resistive memory bit cell during a second stage of the read operation,
wherein a duration of the first stage and a duration of the second stage are equal to half of a duration of the read operation, and wherein the first direction is opposite to the second direction.

21. The system of claim 20, further comprising:
means for developing a first gate voltage at a reference node coupled to a reference cell during the first stage;
means for developing a data voltage at an output node coupled to the resistive memory bit cell, based on the first sensing current and the first gate voltage, during the first stage; and
first storage means for storing the data voltage.

22. The system of claim 21, further comprising:
means for developing a second gate voltage at the reference node during the second stage; and
means for developing a reference voltage at the output node, based on the second sensing current and the second gate voltage during the second stage; and
second storage means for storing the reference voltage.

23. The system of claim 22, further comprising means for equalizing the output node and the reference node at starting points of the first stage and the second stage.

24. The system of claim 22, further comprising, means for amplifying a difference between the data voltage at the output node developed in the first stage and the reference voltage at the output node developed in the second stage.

25. The system of claim 21, wherein a probability of a read disturbance occurring on the resistive memory bit cell is limited to at most one of the first stage or the second stage.

26. The system of claim 21, wherein the resistive memory bit cell is a magnetoresistive random access memory (MRAM) or magnetic tunnel junction (MTJ) bit cell.
